(19) United States
(12) Patent Application Publication
(10) Pub. No.: US 2002/0126303 A1
(43) Pub. Date: Sep. 12, 2002

(54) Printer having scanning function, color converting device and color converting method

(76) Inventor: Kazumi Yamada, Nagano-ken (JP)

Correspondence Address: MATTINGLY, STANGER & MALUR, P.C., 1800 DIAGONAL ROAD, SUITE 370, ALEXANDRIA, VA, 22314, US

(21) Appl. No.: 10/081,201

(22) Filed: Feb. 25, 2002

(30) Foreign Application Priority Data
Feb. 26, 2001 (JP) 2001-050255

(51) Int. Cl. B41J 1/00; G06F 15/00; G03F 3/08

(52) U.S. Cl. 358/1.9; 358/518

(57) ABSTRACT

A lookup table used for converting RGB signals to CMYK signals is formed so that all the CMYK signals are converted to black (K)-100% when each of RGB is in a predetermined range from a value indicating the deepest color state, and also converted to 0% (white) when each of RGB is in a predetermined range from a value indicating the lightest color state. With this setting, when a read-out original is printed in the printer having a scanning function, a black character portion can be printed with clear black while removing the background.

### BACKGROUND OF THE INVENTION

1. Field of the Invention

The present invention relates to a printer, and particularly to a printer having a scanning function.

2. Description of the Invention

There has been known a printer which is equipped with a scanning function to enhance an added value of the printer. Such a printer can be used not only to read photographs, originals, etc. into a computer by using its scanning function, but also as a color copying machine by directly printing the originals, etc. thus read by using the scanning function.

In general, the scanning function of the printer is performed by reading out an original as well as decomposing it into color components of RGB, and then the printer converts the color components of RGB to color components of CMYK for printing. The color conversion is normally carried out by referring to a color conversion table called as “lookup table”.

In a case where a general original having black-color characters on a sheet having white background is read out and then printed, from the viewpoint of readability it is preferable that the characters are printed with clear black and nothing is printed on the white-background portion of the sheet. However, under some conditions of originals from which characters are read out, the black color of the characters is, for example, faint or blurred. If the original is read out and printed in such a case, the characters, etc. which are desired to be printed with only black ink would be printed with black-like color generated by plural color ink materials.

Furthermore, when the sheet of an original is not pure white, but slightly colored like recycled paper, the ground color of the sheet itself may be printed.

### SUMMARY OF THE INVENTION

The present invention has an object to print a black character portion of a read-out original with clear black color when the original is read-out and printed by using a printer having a scanning function.

The present invention has another object to print a read-out original while removing the background of the original.

In order to attain the above objects, according to the present invention, there is provided a printer having a scanning function for reading and printing an original. The printer comprises color converting means for converting a first color component signal based on the original thus read into a second color component signal used for printing, by referring to a lookup table. The lookup table is formed so that the second color component represents black when each of the color signals constituting the first color component signal is in the range from a value indicating the deepest color state to a predetermined value.

This enables the black character portion of the original to be printed with clear black.

Furthermore, in order to attain the above object, according to the present invention, there is a printer having a scanning function for reading and printing an original. The printer comprises color converting means for converting a first color component signal based on the original thus read into a second color component signal used for printing, by referring to a lookup table. Then, the lookup table is formed so that the second color component represents white when each of the color signals constituting the first color component signal is in the range from a value indicating the lightest color state to a predetermined value.

This enables the printer to remove the background of the original.

### BRIEF DESCRIPTION OF THE DRAWINGS

FIG. 1 is a block diagram showing the construction of the present invention;

FIG. 2 is a flowchart showing the processing of a printer 10 having a scanning function according to a first embodiment;

FIGS. 3A and 3B are diagrams showing the processing of performing gradation correction on every color of RGB in the first embodiment, wherein

FIG. 3A is a diagram showing gamma 321 for gradation correction, and

FIG. 3B is a diagram illustrating a conception of the gradation correction;

FIG. 4 is a flowchart showing the processing of a printer 10 having a scanning function according to a second embodiment;

FIG. 5 is a diagram showing conventional gamma which can be used in the second embodiment;

FIGS. 6A and 6B are diagrams showing a conception of lookup tables, wherein

FIG. 6A is a conceptional diagram showing a conventional lookup table, and

FIG. 6B is a conceptional diagram showing a lookup table used in this embodiment;

FIG. 7 is a conceptional diagram when data are omitted from the lookup table; and

FIG. 8 is a conceptional diagram showing an effect when data are omitted from the lookup table.

### DETAILED DESCRIPTION OF THE PREFERRED EMBODIMENTS

Preferred embodiments according to the present invention will be described with reference to the accompanying drawings.

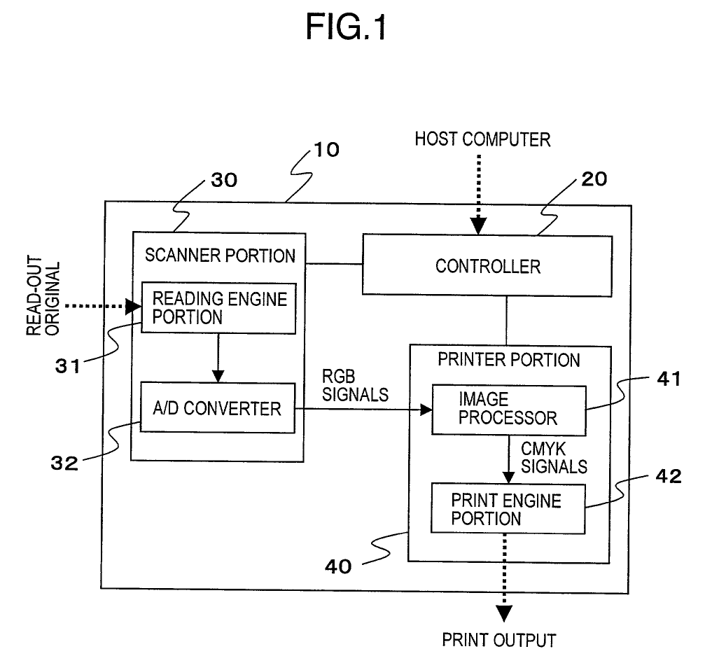

FIG. 1 is a block diagram showing the construction of the present invention.

In FIG. 1, a printer 10 having a scanning function (hereinafter merely referred to as “printer”) comprises a controller 20 for controlling the processing in the printer 10, a scanner portion 30 for reading an original and converting the original thus read to RGB signals (R: red, G: green, B: blue), and a printer portion 40 for converting the RGB signals to CMYK signals (C: cyan, M: magenta, Y: yellow, K :black) and performing a printing operation. The printer 10 can print the original read out by the scanner portion 30 in the printer portion 40, and also can read print data transmitted from a host computer connected to the controller 20 and print out the print data. When the print data transmitted from the host computer is an RGB signal, the printer 10 converts the RGB signal to CMYK signal and then carries out the printing operation. As described above, the printer 10 can also function as a color-converting device.

The scanner portion 30 comprises a light source, a lens, a scanning motor, a CCD (charge coupled device) sensor, etc., and has a reading engine portion 31 and an A/D converter 32. The reading engine portion 31 scans the original while irradiating light to the original, and guides the reflection light thereof to the CCD sensor covered with red (R), green(G) and blue(B) filters. The A/D converter 32 converts into digital signals the reflection light of the original read out by the CCD sensor, and outputs the digital signals on a dot basis as the light-and-shade information of each of the RGB signals. A typical reading method include a flat head method and a film method, however, the reading method is not limited thereto.

The printer portion 40 is equipped with an image processor 41 and a print engine portion 42. The image processor 41 converts the RGB signals to the CMYK signals by referring to a lookup table in which combinations of color conversion are recorded. Thereafter, the CMYK signals are subjected to half-tone processing, etc., and then converted to data having data structure printable in the print engine portion 42. The print engine portion 42 carries out the printing operation on the basis of the data generated by the image processor 41. For example, an ink jet method, a laser method or the like may be used as the printing method of the print engine portion 42.

In this embodiment, for explanation, taken is a case where the RGB signals are converted to the CMYK signals. However, the color combination is not limited to the above embodiment. For example, the RGB signals may be converted to six color signals containing light magenta and light cyan.

As a first embodiment of the present invention, a method of conducting gradation correction on the respective RGB components and printing characters clearly while removing the background will be described.

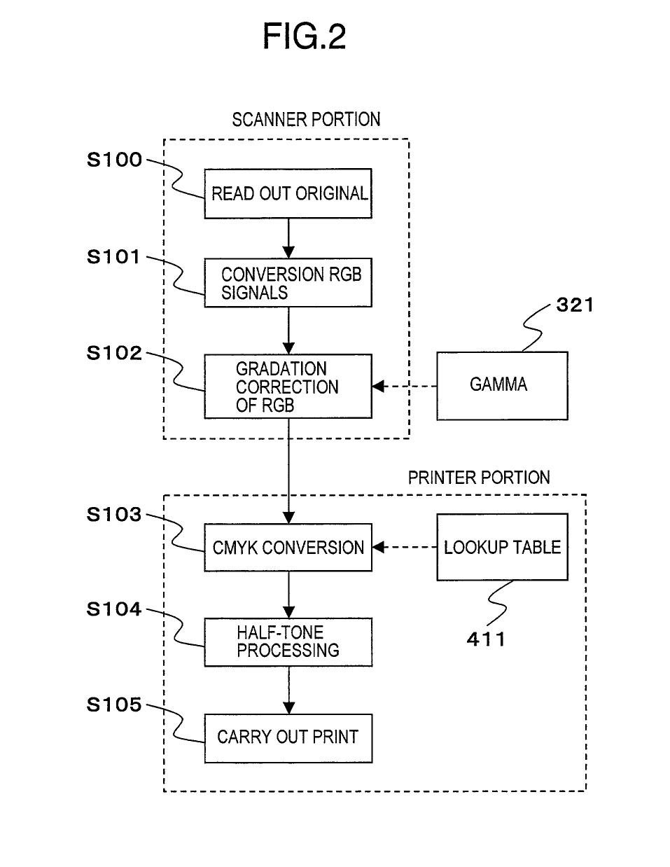

FIG. 2 is a flowchart showing the processing of the printer 10 having the scanning function in the first embodiment.

When reading an original to be printed by using the scanner portion 30 (S100), the A/D converter 32 converts reflection light guided from the original by the reading engine 31 to the voltage of each of the RGB colors. The voltages thus converted are converted to digital values to generate the RGB signals (S101).

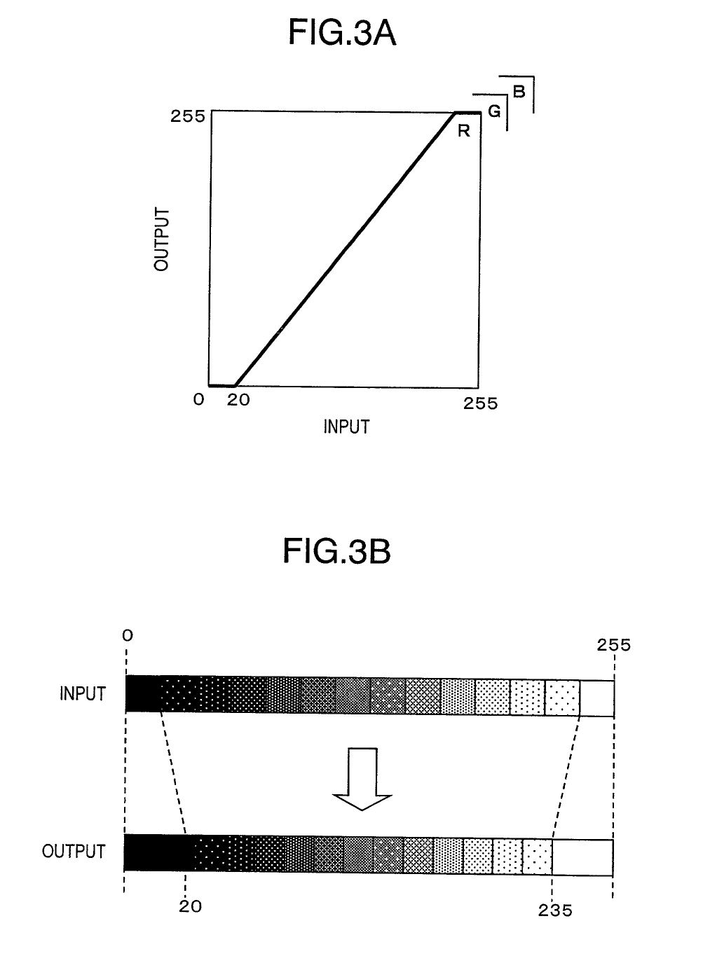

Subsequently, the gradation correction is carried out on every color of RGB by using gamma 321 (S102). This gradation correction processing will be described with reference to FIGS. 3A and 3B.

FIG. 3A is a diagram showing the gamma 321 for the gradation correction in this embodiment.

In this embodiment, each of the RGB signals is assumed to be represented with 256 levels by using 8 bits. As shown in FIG. 3A, the gamma 321 of this embodiment is set so that opposite ends for each of the RGB colors including 20 gradations, that is, a deep color area (0 to 20) and a light color area (235 to 255) are converted to “zero” (deepest color state) and 255 (lightest color state), respectively. The state of “zero” is set to “black” and the state of 255 is set to “white” for all the three colors of RGB. It is needless to say that 20 gradations are set as an example, and thus the number of gradations is not limited to this value. The number of gradations may be set on the basis of a user's instruction. Further, different values may be set for the RGB colors in consideration of the characteristic or the like of the printer.

FIG. 3B is a conceptional diagram showing the gradation correction in this case.

By converting each of the RGB colors with the gamma 321 so as to expand the deepest portion and the lightest portion as described above, a black-like portion, that is, a black character portion is converted to an RGB signal (0,0,0) representing clear black, and a white-like portion, that is, a portion having the ground color of the sheet is converted to an RGB signal (255, 255, 255) representing white.

Thereafter, the RGB signals are converted to respective colors of CMYK which are printable by the print engine (S103). This conversion is generally carried out by referring to a lookup table (LUT) 411. The lookup table 411 is a table storing correspondence of the respective values of RGB with the respective values of CMYK. However, it is not realistic that all the combinations of the 256 gradations of the respective RGB colors are stored as data because this needs a large amount of storage capacity. Therefore, usually, 256 gradations of each color of RGB are sorted by some grids to achieve discretely-associated CMYK data. For intermediate RGB signal values, an interpolation operation is carried out to perform the color conversion.

At this time, the RGB signal (0,0,0) is converted to the CMYK signal (0,0,0,100), that is, 100%-black, and the RGB signal (255, 255, 255) is converted to the CMYK signal (0,0,0,0), that is, so that no print is carried out. Accordingly, the print operation can be performed so that characters are printed with clear black and the background portion is removed.

After the gradation processing of half-toning, etc. (S104) is carried out, the print is carried out in the print engine portion 42.

Next, a second embodiment according to the present invention will be described.

In this embodiment, a method of printing characters clearly by using a lookup table while removing the background will be described.

In the first embodiment, the gradation correction is independently carried out for each of the RGB colors. Therefore, in the RGB gradation correction (S102), for example, an RGB signal (245, 245, 230) is converted to (255, 255, about 230) by the gamma 321. That is, R(red) and G(green) components are missed (lightest state) and only B(blue) component remains. Therefore, there may occur a case where minute tone of color cannot be reproduced. In the second embodiment, this problem can be further overcome. That is, in this embodiment, characters can be printed clearly while removing the background, and also minute tone of color can be represented for colors close to black or white.

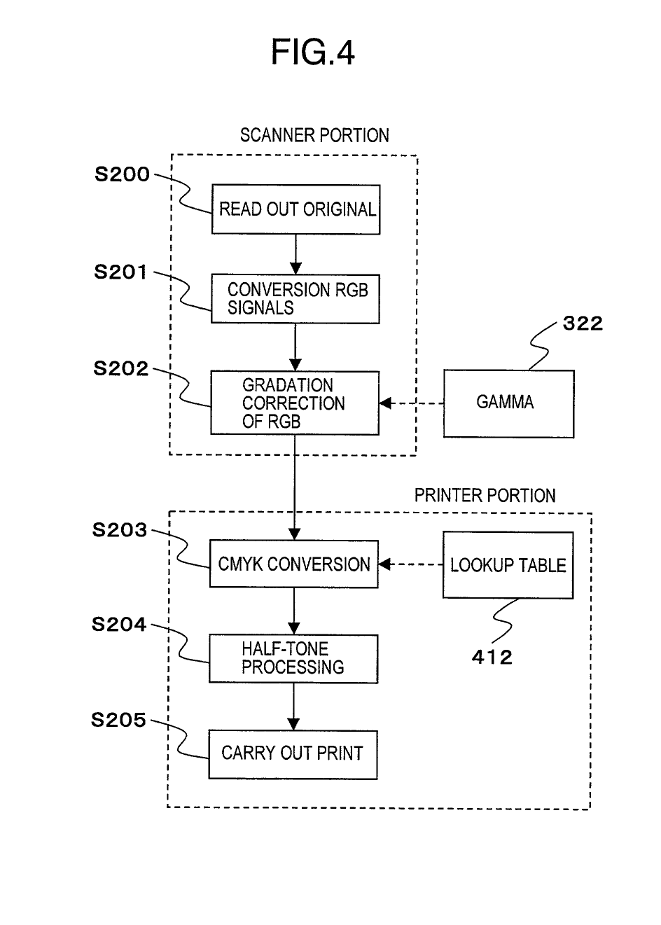

FIG. 4 is a flowchart showing the processing of the printer 10 having the scanning function in the second embodiment.

Original reading processing (S200) and RGB signal conversion processing (S201) are the same as the first embodiment.

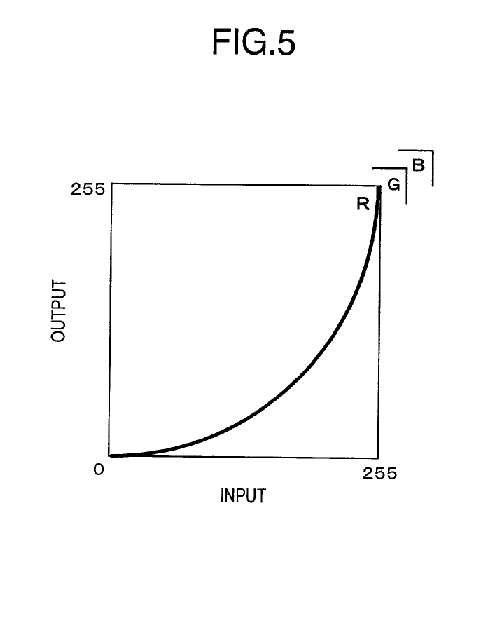

In this embodiment, gamma 322 to be used in RGB gradation correction processing (S202) is arbitrary, and for example, a conventional gamma as shown in FIG. 5 can be used. This is gamma for enhancing the contrast of an input image.

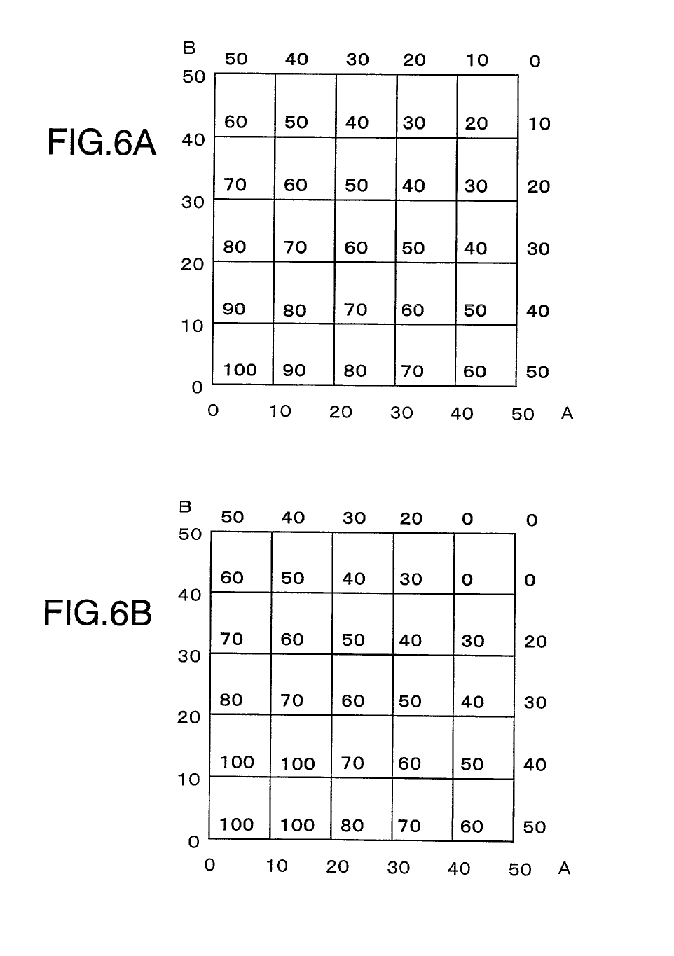

In the processing (S203) of converting the RGB signals to respective colors of CMYK, a lookup table 412 is referred to in this embodiment. FIGS. 6A and 6B are conceptional diagrams showing lookup tables. FIG. 6A is a conceptional diagram of a conventional lookup table, and FIG. 6B is a conceptional diagram of a lookup table 412 used in this embodiment.

In order to simplify the description, a two-dimensional lookup table is used as an example. That is, a table for converting a color (corresponding to RGB signal) represented by two signal values (A, B) of A and B to a color (corresponding to CMYK signal) represented by one value is used. In FIGS. 6A and 6B, a lateral axis of the grid represents the signal values of A, and a vertical axis of the grid represents the signal values of B. The color before the conversion is assumed to be represented with 50 gradations for each of A and B.

The cross points of the grids represents values indicating colors after the conversion. The colors after the conversion are represented with 100 levels. In the colors after the conversion, 100 represents “black”, and 0 represents “white”.

For example, the color represented by (30, 20) is converted to the color represented by “50”. An intermediate value, for example, (15, 25) is interpolatively determined by using the value of each apex (the cross point of the grids) of, for instance, a rectangle or triangle containing the intermediate value. That is, in the conventional lookup table, only the color represented by (0,0) is converted to black represented by “100”, and only the color represented by (50, 50) is converted to white represented by “0”.

In the conceptual diagram of the lookup table used in the embodiment shown in FIG. 6B, “100” is set to the points of the grid represented by (0,0), (10,0), (0,10) and (10,10), and “0” is set to the points of the grids represented by (50,50), (40,50), (50,40) and (40,40). That is, an area indicating “100” and an area indicating “0” are expanded.

Therefore, the colors represented by (0,10), (10,10), etc. are converted to black, and the colors represented by (40,40), (50,40), etc. are converted to white. Therefore, characters can be clearly printed with black while the background is removed.

The color represented by (5,20) is converted to the color represented by about “75” through the interpolative calculation. In the first embodiment using the gamma 321, “5” is rounded to zero so that (5,20) is converted to (0,20). Therefore, the color represented by (5,20) is converted to the color represented by “80”, thereby losing minute tone of color.

As described above, according to this embodiment, characters can be printed with black while the background is printed with white without damaging minute tone of color.

By expanding the image of the lookup table to the three dimension comprising the three axes of RGB and giving the values of the respective CMYK colors for the respective cross points of the grids, it can be set as the lookup table used in this embodiment.

In this case, when the color conversion data included in the lookup table 412 is expressed in the manner of (R,G,B)→(C %, M %, Y %, K %), these may be as follows:

(0,0,0)→(0,0,0,100)

(0,0,10)→(0,0,0,100)

(0,0,20)→(10,0,10,80)

. . .

(0,0,235)→(33,33,33,0)

(0,0,255)→(33,33,33,0)

. . .

(0,10,0)→(0,0,0,100)

. . .

(255,255,255)→(0,0,0,0)

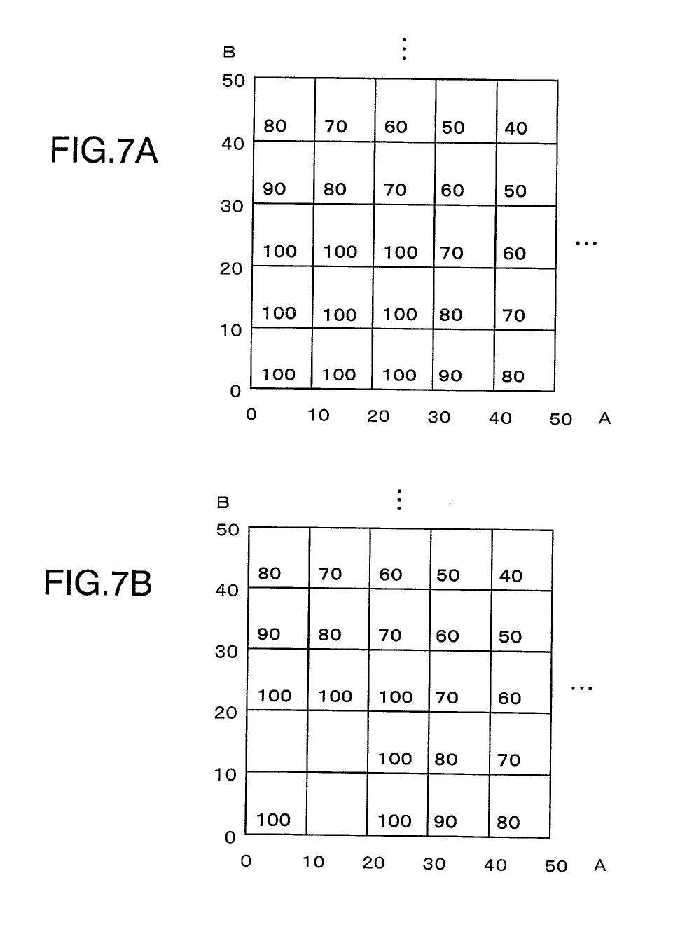

Although, in general, the interval of the grids in the lookup table is set to the equal interval, and the number and interval of grids may be set to any values. Further, the interval is not necessarily set to the equal interval. At this time, points of 100 representing black (0 representing white) may occur continuously as shown in FIG. 7A in accordance with the manner of arranging the grids and the manner of setting the black (white) converting range. That is, in FIG. 6A, the points of (0,0), (5,0), (10,0), (5,0), (5,5), (5,10), (10,0), (10,0) and (10,0) are set to “100”. In such a case, the value of “100” can be calculated by the interpolation, so that some data can be omitted from the lookup table as shown in FIG. 7B.

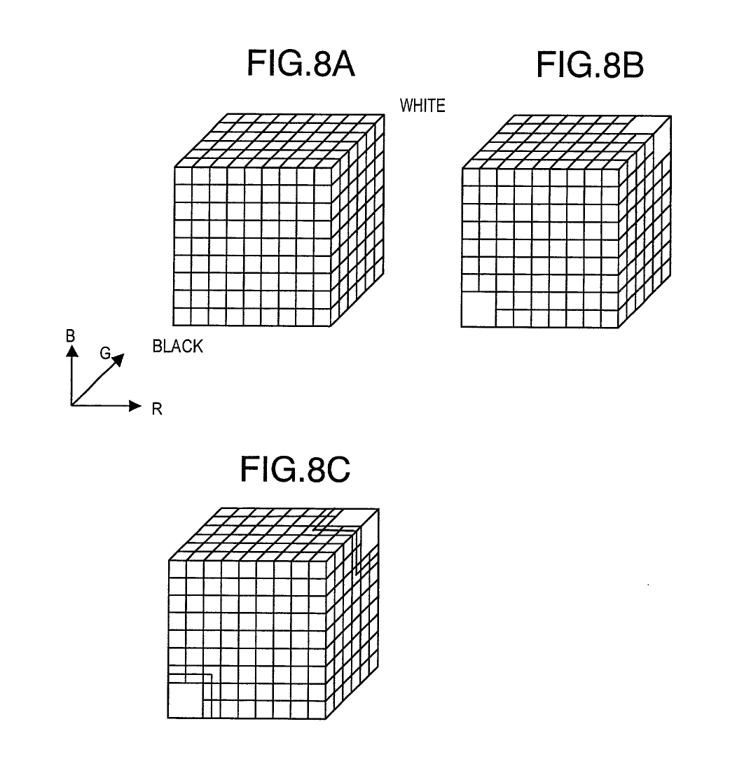

By omitting a part of data from the lookup table as described above, the size of the lookup table is reduced and the memory can be spared. FIGS. 8A and 8B are conceptual diagrams showing the lookup table. FIG. 8A is a conceptual diagram showing the conventional lookup table in which the grid interval is fixed, and FIG. 8B is a conceptual diagram when a part of data is omitted from the lookup table.

Further, by using the memory capacity corresponding to the data thus omitted, the grid interval of the other portion may be narrowed. In this case, the precision of the interpolation calculation can be enhanced. Accordingly, the color conversion to CMYK can be more accurately performed at the same size of the lookup table. FIG. 8C is a conceptual diagram of the lookup table in this case.

It is preferable, in the present invention, that a setting for use/non-use of gamma or the lookup table is prepared in accordance with a user's instruction or the like. This setting enables color reproduction to be accurately performed on a black-like portion and a white-like portion by using the conventional gamma or the lookup table, for example, in the case that originals to be read is such as photographs.

In the second embodiment, described is an example that RGB is converted to CMYK by using a lookup table. However, the present invention is not limited to this embodiment. For example, the present invention may be applied to the conversion from RGB signals to RGB signals, the conversion from CMYK signals to CMYK signals, etc. That is, the present invention may be applied to a general case where a subject color for conversion comprising plural color signals is converted to a target color comprising plural color signals by using the lookup table.

As described above, according to the present invention, when a read-out original is printed in a printer having a scanning function, a black character portion can be printed with clear black. Further, the background can be removed in the printing operation.

What is clamed is:

1. A printer having a scanning function for reading and printing an original, comprising:
color converting means for converting a first color component signal based on the thus read original into a second color component signal used for printing by referring to a lookup table,
wherein said lookup table is formed so that the second color component represents black when each of the color signals constituting the first color component signal is in the range from a value indicating the deepest color state to a predetermined value.

2. A printer having a scanning function for reading and printing an original, comprising:
color converting means for converting a first color component signal based on the original thus read into a second color component signal used for printing by referring to a lookup table,
wherein said lookup table is formed so that the second color component represents white when each of the color signals constituting the first color component signal is in the range from a value indicating the lightest color state to a predetermined value.

3. The printer having the scanning function as claimed in claim 1 or 2, wherein the first color component signal and the second color component signal are constructed by plural signals indicating colors.

4. The printer having the scanning function as claimed in claim 1 or 2, wherein the first color component signal is an RGB signal, and the second color component signal is a CMYK signal.

5. The printer having the scanning function as claimed in claim 1, wherein said lookup table has grids set to be non-equidistant, and in the vicinity of a portion where said first color component signal indicates the deepest color state, the distance between the grids is set to be large.

6. The printer having the scanning function as claimed in claim 1, wherein:
said lookup table is expressed by grids including discontinuous values; and
said grids are set to be non-equidistant, and a distance between said grids, in the vicinity of a portion where each of color signals constituting the first color component signal indicates the deepest color state, is set to be wide.

7. The printer having the scanning function as claimed in claim 2, wherein:
said lookup table is expressed by grids including discontinuous values; and
said grids are set to be non-equidistant, and a distance between said grids, in the vicinity of a portion where each of color signals constituting the first color component signal indicates the lightest color state, is set to be wide.

8. The printer having the scanning function as claimed in claim 1 or 2, wherein said color converting means has a second lookup table different from said lookup table, and converts the first color component signal based on the read-out original to the second color component signal used for printing by selectively referring to any one of said lookup table and said second lookup table.

9. The printer having the scanning function as claimed in claim 8, wherein said color converting means selects any one of said lookup table and said second lookup table in accordance with a user's setting.

10. A color converting device for converting a subject color for conversion comprising a combination of color signals to a target color comprising a combination of color signals,
wherein when each of the color signals of the subject color is in the range from a value indicating the deepest color state to a predetermined value, color conversion is carried out by using a lookup table formed in order that the target color is to be black.

11. A color converting device for converting a subject color for conversion comprising a combination of color signals to a target color comprising a combination of color signals,
wherein when each of the color signals of the subject color is in the range from a value indicating the lightest color state to a predetermined value, color conversion is carried out by using a lookup table formed in order that the target color is to be white.

12. The color converting device as claimed in claim 10 or 11, wherein the subject color for conversion is constructed by RGB and the target color is constructed by CMYK.

13. The color converting device as claimed in claim 10 or 11, wherein:
said lookup table is expressed by grids including discontinuous values; and
said grids are set to be non-equidistant, and grids in a portion where the target color indicates black and grids in a portion where the target color indicates white, have a larger distance than grids in other portions.

14. A color converting method for converting a subject color for conversion comprising a combination of color signals to a target color comprising a combination of color signals,
wherein color conversion is carried out so that the target color is to be black when each of the color signals constituting the subject color is in the range from a value indicating the deepest color state to a predetermined value.

15. A color converting method for converting a subject color for conversion comprising a combination of color signals to a target color comprising a combination of color signals,
wherein color conversion is carried out so that the target color is to be white when each of the color signals constituting the subject color is in the range from a value indicating the lightest color state to a predetermined value.

16. The color converting method as claimed in claim 14 or 15, wherein the color conversion is carried out by referring to a lookup table predetermined with respect to correspondence between the color signal combination of the subject color and the color signal combination of the target color.
